(19) United States
(12) Patent Application Publication
(10) Pub. No.: US 2026/0182037 A1
(43) Pub. Date: Jun. 25, 2026

(54) Display Substrate and Display Apparatus

(71) Applicant: BOE Technology Group Co., Ltd., Beijing (CN)

(72) Inventors: Chuanxiang XU, Beijing (CN); Shi SHU, Beijing (CN); Qi YAO, Beijing (CN); Guangcai YUAN, Beijing (CN); Yang YUE, Beijing (CN); Xiang LI, Beijing (CN); Yong YU, Beijing (CN); Xinhua LIU, Beijing (CN)

(21) Appl. No.: 18/836,364

(22) PCT Filed: Oct. 27, 2023
(86) PCT No.: PCT/CN2023/127305

§ 371 Date: Aug. 7, 2024

(51) Int. Cl. H10D 86/60

(52) U.S. Cl. CPC H10D 86/60

(57) ABSTRACT

A display substrate and a display apparatus are provided. The display substrate includes a plurality of island regions arranged at intervals, a hollowed-out region located between adjacent island regions, and a bridge region connecting the adjacent island regions to each other. The bridge region includes a lead line including a connection section (40), a bending section (60), and a plurality of extension sections (50). The connection section (40) is connected with an island region and an extension section (50), and the bending section (60) connects adjacent extension sections (50). A maximum line width of the connection section (40) is greater than or equal to a maximum line width of at least one of the plurality of extension sections (50), and the maximum line width of at least one of the plurality of extension sections (50) is greater than or equal to a maximum line width of the bending section (60).

### CROSS-REFERENCE TO RELATED APPLICATION

The present application is a U.S. National Phase Entry of International Application No. PCT/CN 2023/127305 having an international filing date of Oct. 27, 2023, contents of which are incorporated into the present application by reference.

### TECHNICAL FIELD

The present disclosure relates to, but is not limited to, the field of display technologies, and more particularly, to a display substrate and a display apparatus.

### BACKGROUND

Flexible display is a research hotspot in recent years. With the mass production of folding mobile phones, people have begun to study the upgraded version of folding display, that is, the stretchable display. At present, the stretchable display substrate uses an island bridge structure, where a display light emitting unit is placed in the island region, and a connection line is placed in the bridge region, so as to realize the stretching function of the display panel. At present, the connection line of the bridge region is generally made on a flexible base substrate (such as PI, etc.), and the stretchability of the PI itself is only about 5%, which affects the final stretchability of the display apparatus.

### SUMMARY

The following is a summary of subject matters described herein in detail. This summary is not intended to limit the protection scope of claims.

In one aspect, the present disclosure provides a display substrate including a plurality of island regions arranged at intervals, a hollowed-out region located between adjacent island regions, and a bridge region connecting the adjacent island regions to each other. The bridge region includes a lead line, the lead line includes a connection section, a bending section, and a plurality of extension sections. The bending section connects adjacent extension sections, a first end of the connection section is connected with an island region, and a second end of the connection section is connected with an extension section. A maximum line width of the connection section is greater than or equal to a maximum line width of the extension section connected therewith, and a maximum line width of the extension section is less than or equal to a maximum line width of the bending section connected therewith.

In an exemplary implementation, a ratio of a maximum line width of at least one of the adjacent extension sections to a maximum spacing between edges of the adjacent extension sections is greater than or equal to 1/20 and less than or equal to 20.

In an exemplary implementation, a ratio of a maximum line width of at least one of the adjacent extension sections to a maximum spacing between the edges of the adjacent extension sections is greater than or equal to ¼ and less than or equal to 4.

In an exemplary implementation, the lead line is in a serpentine shape in a plane parallel to the display substrate.

In an exemplary implementation, in a plane parallel to the display substrate, a first end of the lead line is connected with a first end of an edge portion of one of the adjacent island regions, a second end of the lead line is connected with a second end of an edge portion of the other of the adjacent island regions, and the first end and the second end are opposite ends of edge portions of the island regions.

In an exemplary implementation, central axes of the adjacent extension sections are substantially parallel; and/or, the central axes of the adjacent extension sections intersect with each other, and the edges of the adjacent extension sections are away from each other; and/or, the central axes of the adjacent extension sections intersect with each other, and the edges of the adjacent extension sections are close to each other.

In an exemplary implementation, a shape of the bending section is arc-shaped.

In an exemplary implementation, the bending section has an opening, the lead line includes a plurality of bending sections, and openings of adjacent bending sections are oriented oppositely; and/or, the bending section has an opening, the lead line includes one bending section, at least part of lead lines are adjacent to each other, and the openings of the bending sections of adjacent lead lines are oriented oppositely.

In an exemplary implementation, at least two lead lines are connected between adjacent island regions, the at least two lead lines are adjacent to each other, and adjacent lead lines are mirrored.

In an exemplary implementation, the plurality of island regions are arranged at intervals to form an island region row, the bridge region includes a first lead line, the first lead line is in a serpentine shape, and the first lead line connects adjacent island regions in the island region row. The first lead line includes a first connection section, a first extension section, a first bending section, a second extension section, a second bending section, a third extension section and a second connection section connected in sequence. A first end of the first connection section is connected with one of the adjacent island regions in the island region row, a second end of the first connection section is connected with a first end of the first extension section, a second end of the first extension section is connected with a first end of the first bending section, a second end of the first bending section is connected with a first end of the second extension section, a second end of the second extension section is connected with a first end of the second bending section, a second end of the second bending section is connected with a first end of the third extension section, a second end of the third extension section is connected with a first end of the second connection section, and a second end of the second connection section is connected with the other of the adjacent island regions in the island region row.

In an exemplary implementation, the plurality of island regions are arranged at intervals to form an island region row, the bridge region includes a first lead line, the first lead line is in a serpentine shape, and the first lead line connects adjacent island regions in the island region row. The first lead line includes a fifth connection section, a seventh extension section, a fifth bending section, an eighth extension section and a sixth connection section connected in sequence. A first end of the fifth connection section is connected with one of the adjacent island regions, a second end of the fifth extension section is connected with a first end of the seventh extension section, a second end of the seventh extension section is connected with a first end of the fifth bending section, a second end of the fifth bending section is connected with a first end of the eighth extension section, a second end of the eighth extension section is connected with a first end of the sixth connection section, and a second end of the sixth connection section is connected with the other of the adjacent island regions.

In an exemplary implementation, the plurality of island regions are arranged at intervals to form an island region column, the bridge region includes a second lead line, the second lead line is in a serpentine shape, and the second lead line connects adjacent island regions in the island region column. The second lead line includes a third connection section, a fourth extension section, a third bending section, a fifth extension section, a fourth bending section, a sixth extension section and a fourth connection section connected in sequence. A first end of the third connection section is connected with one of the adjacent island regions in the island region column, a second end of the third connection section is connected with a first end of the fourth extension section, a second end of the fourth extension section is connected with a first end of the third bending section, a second end of the third bending section is connected with a first end of the fifth extension section, a second end of the fifth extension section is connected with a first end of the fourth bending section, a second end of the fourth bending section is connected with a first end of the sixth extension section, a second end of the sixth extension section is connected with a first end of the fourth connection section, and a second end of the fourth connection section is connected with the other of the adjacent island regions in the island region column.

In an exemplary implementation, the plurality of island regions are arranged at intervals to form an island region column, the bridge region includes a second lead line, the second lead line is in a serpentine shape, and the second lead line connects adjacent island regions in the island region column. The second lead line includes a seventh connection section, a ninth extension section, a sixth bending section, a tenth extension section and an eighth connection section connected in sequence. A first end of the seventh connection section is connected with one of the adjacent island regions, a second end of the seventh connection section is connected with a first end of the ninth extension section, a second end of the ninth extension section is connected with a first end of the sixth bending section, a second end of the sixth bending section is connected with a first end of the tenth extension section, a second end of the tenth extension section is connected with a first end of the eighth connection section, and a second end of the eighth connection section is connected with the other of the adjacent island regions. In an exemplary implementation, in a cross section parallel to the display substrate, a shape of the island region includes at least one of a rectangle, a rounded rectangle, an oblong, an oval, a circle, and a heptagon.

In an exemplary implementation, in a cross section parallel to the display substrate, a shape of the island region includes at least one of a rectangle and a rounded rectangle, and the island region includes a first edge portion parallel to a first direction. Alternatively, an included angle between the first edge portion and the first direction is greater than 0 degree and less than 90 degrees.

In an exemplary implementation, the bridge region further includes a flexible base substrate, a lead line disposed on a side of the flexible base substrate, and a flexible film layer disposed on a side of the lead line away from the flexible base substrate. A surface of the lead line close to the flexible base substrate is in direct contact with the flexible base substrate, and a surface of the lead line close to the flexible film layer is in direct contact with the flexible film layer.

In an exemplary implementation, the bridge region includes a flexible base substrate, a lead line disposed on a side of the flexible base substrate, and a flexible film layer disposed on a side of the lead line away from the flexible base substrate. A gap is provided between a surface of the lead line close to the flexible base substrate and the flexible base substrate, and a surface of the lead line close to the flexible film layer is in direct contact with the flexible film layer.

In an exemplary implementation, the bridge region includes a flexible base substrate, a lead line disposed on a side of the flexible base substrate, and a flexible film layer disposed on a side of the lead line away from the flexible base substrate. A surface of the lead line close to the flexible base substrate is in direct contact with the flexible base substrate, and a suspended portion is disposed between a surface of the lead line close to the flexible film layer and the flexible film layer.

In an exemplary implementation, the bridge region includes a flexible base substrate, a lead line disposed on a side of the flexible base substrate, and a flexible film layer disposed on a side of the lead line away from the flexible base substrate. A first suspended portion is disposed between a surface of the lead line close to the flexible base substrate and the flexible base substrate, and a second suspended portion is disposed between a surface of the lead line close to the flexible film layer and the flexible film layer.

In an exemplary implementation, the lead line is in a serpentine shape in a plane perpendicular to the display substrate.

In an exemplary implementation, a bump is provided on a surface of the lead line close to the flexible base substrate, and the bump is in direct contact with the flexible base substrate.

In an exemplary implementation, the bridge region includes a flexible base substrate, a lead line disposed on a side of the flexible base substrate, and a flexible film layer disposed on a side of the lead line away from the flexible base substrate. A bump is disposed on a surface of the lead line close to the flexible base substrate, the bump is in direct contact with the flexible base substrate, a first suspended portion is disposed between at least a part of the surface of the lead line close to the flexible base substrate and the flexible base substrate, and a second suspended portion is disposed between a surface of the lead line close to the flexible film layer and the flexible film layer.

In an exemplary implementation, the bridge region includes a flexible base substrate, a lead line disposed on a side of the flexible base substrate, and a flexible film layer disposed on a side of the lead line away from the flexible base substrate. The bridge region further includes a first anti-adhesion layer disposed on a side of the flexible base substrate close to the lead line, and an orthographic projection of the first anti-adhesion layer on the flexible base substrate overlaps with an orthographic projection of the lead line on the flexible base substrate; and/or, the bridge region further includes a second anti-adhesion layer disposed on a side of the flexible film layer close to the lead line, and an orthographic projection of the second anti-adhesion on the flexible base substrate overlaps with an orthographic projection of the lead line on the flexible base substrate.

In another aspect, the present disclosure also provides a display apparatus, including the display substrate described above.

Other aspects of the present disclosure may be comprehended after the drawings and the detailed description are read and understood.

### BRIEF DESCRIPTION OF DRAWINGS

The drawings are used to provide understanding of technical solution of the present disclosure, and form a part of the specification. The drawings and embodiments of the present disclosure are adopted to explain the technical solution of the present disclosure, and do not form limitations on the technical solution of the present disclosure.

FIG. 1 is a schematic diagram of a structure of a display apparatus according to an embodiment of the present disclosure.

FIG. 2 is a schematic diagram of a planar structure of a display substrate according to an embodiment of the present disclosure.

FIG. 3 is a schematic diagram of a planar structure of a display substrate according to an embodiment of the present disclosure.

FIG. 4 is a schematic diagram of a planar structure of a display substrate according to an embodiment of the present disclosure.

FIG. 5 is a schematic diagram of a planar structure of a display substrate according to an embodiment of the present disclosure.

FIG. 6a is a schematic diagram of a planar structure of a first island region in a display substrate according to an embodiment of the present disclosure.

FIG. 6b is a schematic diagram of a planar structure of a first island region in another display substrate according to an embodiment of the present disclosure.

FIG. 7a is a schematic diagram of a planar structure of a first island region in another display substrate according to an embodiment of the present disclosure.

FIG. 7b is a schematic diagram of a planar structure of a first island region in another display substrate according to an embodiment of the present disclosure.

FIG. 7c is a schematic diagram of a planar structure of a first island region in another display substrate according to an embodiment of the present disclosure.

FIG. 7d is a schematic diagram of a planar structure of a first island region in another display substrate according to an embodiment of the present disclosure.

FIG. 8a is a schematic diagram of a planar structure of a first island region in another display substrate according to an embodiment of the present disclosure.

FIG. 8b is a schematic diagram of a planar structure of a first island region in another display substrate according to an embodiment of the present disclosure.

FIG. 8c is a schematic diagram of a planar structure of a first island region in another display substrate according to an embodiment of the present disclosure.

FIG. 8d is a schematic diagram of a planar structure of a first island region in another display substrate according to an embodiment of the present disclosure.

FIG. 9a is a schematic diagram of a planar structure of a first island region and a first bridge region in a display substrate according to an embodiment of the present disclosure.

FIG. 9b is a schematic diagram of a planar structure of a lead line in a display substrate according to an embodiment of the present disclosure.

FIG. 10a is a schematic diagram of a planar structure of an extension section of a lead line in a display substrate according to an embodiment of the present disclosure.

FIG. 10b is a schematic diagram of a planar structure of an extension section of a lead line in another display substrate according to an embodiment of the present disclosure.

FIG. 10c is a schematic diagram of a planar structure of an extension section of a lead line in another display substrate according to an embodiment of the present disclosure.

FIG. 11a is a schematic diagram of a planar structure of a first lead line in a display substrate according to an embodiment of the present disclosure.

FIG. 11b is a schematic diagram of a planar structure of a second lead line in a display substrate according to an embodiment of the present disclosure.

FIG. 12a is a schematic diagram of a cross sectional structure of a first island region and a first bridge region in a display substrate according to an embodiment of the present disclosure.

FIG. 12b is a schematic diagram of a cross sectional structure of a first island region and a first bridge region in another display substrate according to an embodiment of the present disclosure.

FIG. 12c is a schematic diagram of a cross sectional structure of a first island region and a first bridge region in another display substrate according to an embodiment of the present disclosure.

FIG. 12d is a schematic diagram of a cross sectional structure of a first island region and a first bridge region in another display substrate according to an embodiment of the present disclosure.

FIG. 12e is a schematic diagram of a cross sectional structure of a first island region and a first bridge region in another display substrate according to an embodiment of the present disclosure.

FIG. 12f is a schematic diagram of a cross sectional structure of a first island region and a first bridge region in another display substrate according to an embodiment of the present disclosure.

FIG. 12g is a schematic diagram of a cross sectional structure of a first island region and a first bridge region in another display substrate according to an embodiment of the present disclosure.

FIG. 12h is a schematic diagram of a cross sectional structure of a first island region and a first bridge region in another display substrate according to an embodiment of the present disclosure.

FIG. 12i is a schematic diagram of a cross sectional structure of a first island region and a first bridge region in another display substrate according to an embodiment of the present disclosure.

FIG. 13 is a schematic diagram of a planar structure of a first island region and a first bridge region in another display substrate according to an embodiment of the present disclosure.

FIG. 14 is a schematic diagram of a planar structure of a first island region and a first bridge region in another display substrate according to an embodiment of the present disclosure.

FIG. 15 is a schematic diagram of a planar structure of a first island region and a first bridge region in another display substrate according to an embodiment of the present disclosure.

FIG. 16 is a schematic diagram of a planar structure of a first island region and a first bridge region in another display substrate according to an embodiment of the present disclosure.

### DETAILED DESCRIPTION

To make the objectives, technical solutions, and advantages of the present disclosure clearer, embodiments of the present disclosure will be described in detail below with reference to the drawings. It is to be noted that implementations may be implemented in multiple different forms. Those of ordinary skills in the art can easily understand such a fact that implementations and contents may be transformed into various forms without departing from the purpose and scope of the present disclosure. Therefore, the present disclosure should not be explained as being limited to the contents recorded in the following implementations only. The embodiments and features in the embodiments of the present disclosure may be randomly combined with each other if there is no conflict.

Scales of the drawings in the present disclosure may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present disclosure are schematic structural diagrams only, and one mode of the present disclosure is not limited to shapes, numerical values, or the like shown in the drawings. Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the drawings, not to indicate or imply that involved devices or elements are required to have specific orientations or are structured and operated in the specific orientations but only to easily describe the present specification and simplify the description, and thus should not be understood as limitations on the present disclosure. The positional relationships between the constituent elements may be changed as appropriate according to a direction according to which each constituent element is described. Therefore, appropriate replacements based on situations are allowed, and the positional relationships are not limited to the expressions in the specification.

In the specification, unless otherwise expressly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through middleware, or an internal communication between two elements. Those of ordinary skills in the art may understand specific meanings of the above terms in the present disclosure according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Alternatively, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, in the specification the “source electrode” and the “drain electrode” are interchangeable, and the “source terminal” and the “drain terminal” are interchangeable.

In the specification, “electrical connection” includes connection of constituent elements through an element with a certain electrical action. An “element with a certain electrical action” is not particularly limited as long as electrical signals may be sent and received between the connected constituent elements. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is- 5°or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon, hexagon, etc. in this specification are not strictly defined, and they may be approximate triangle, rectangle, trapezoid, pentagon, hexagon, etc. There may be some small deformations caused by tolerance, and there may be chamfer, arc edge, deformation, etc.

In the present disclosure, “about” refers to that a boundary is not defined so strictly and numerical values within a range of process and measurement errors are allowed.

A display substrate according to an embodiment of the present disclosure includes a plurality of island regions arranged at intervals, a hollowed-out region located between adjacent island regions, and a bridge region connecting the adjacent island regions to each other. The bridge region includes a lead line, and the lead line includes a connection section, a bending section, and a plurality of extension sections. The bending section connects adjacent extension sections, a first end of the connection section is connected with an island region, and a second end of the connection section is connected with an extension section. A maximum line width of the connection section is greater than or equal to a maximum line width of the extension section connected therewith, and a maximum line width of the extension section is less than or equal to a maximum line width of the bending section connected therewith.

FIG. 1 is a schematic diagram of a structure of a display apparatus according to an embodiment of the present disclosure. As shown in FIG. 1, the display apparatus may include a timing controller, a data driver, a scan driver, a light emitting driver, and a pixel array. The timing controller is connected with the data driver, the scan driver, and the light emitting driver, respectively, the data driver is connected with a plurality of data signal lines (D1 to Dn) respectively, the scan driver is connected with a plurality of scan signal lines (S1 to Sm) respectively, and the light emitting driver is connected with a plurality of light emitting signal lines (E1 to Eo) respectively. The pixel array may include a plurality of sub-pixels Pxij, i and j may be natural numbers, at least one sub-pixel Pxij may include a circuit unit and a light emitting unit, and the circuit unit may include at least a pixel drive circuit connected with a scan signal line, a light emitting signal line and a data signal line, respectively. The light emitting unit may include a light emitting device connected with the pixel drive circuit of the circuit unit. In an exemplary implementation, the timing controller may provide the data driver with a gray scale value and a control signal which are suitable for the specification of the data driver, provide the scan driver with a clock signal and a scan start signal and the like which are suitable for the specification of the scan driver, and provide the light emitting driver with a clock signal and an emission stop signal and the like which are suitable for the specification of the light emitting driver. The data driver may generate data voltages to be provided to the data signal lines D1, D2, D3, . . . , and Dn using the gray scale value and the control signal received from the timing controller. For example, the data driver may sample the gray scale value using the clock signal and apply a data voltage corresponding to the gray scale value to the data signal lines D1 to Dn by taking a pixel row as a unit, wherein n may be a natural number. The scan driver may generate scan signals to be provided to the scan signal lines S1, S2, S3, . . . , and Sm by receiving the clock signal and the scan start signal and the like from the timing controller. For example, the scan driver may sequentially provide a scan signal with an on-level pulse to the scan signal lines S1 to Sm. For example, the scan driver may be constructed in a form of a shift register and may generate a scan signal in a manner in which a scan start signal provided in a form of an on-level pulse is transmitted to a next-stage circuit sequentially under control of the clock signal, wherein m may be a natural number. The light emitting driver may generate emission signals to be provided to the light emitting signal lines E1, E2, E3, . . . , and Eo by receiving a clock signal, an emission stop signal and the like from the timing controller. For example, the light emitting driver may sequentially provide an emission signal with an off-level pulse to the light emitting signal lines El to Eo. For example, the light emitting driver may be constructed in a form of a shift register and generate an emission signal in a manner of sequentially transmitting an emission stop signal provided in a form of an off-level pulse to a next-stage circuit under control of the clock signal, wherein o may be a natural number. In an exemplary implementation, the pixel array may be disposed on the display substrate.

In an exemplary implementation, the display substrate may adopt a stretchable structure, the display substrate including a plurality of island regions arranged at intervals from each other provided on a flexible base substrate, a hollowed-out region located between adjacent island regions, and a bridge region connecting the adjacent island regions to each other. Each island region may include one or more pixel units, and each pixel unit includes three (e.g. red, green and blue) or four (e.g. red, green, blue and white) light emitting units for emitting different colors. The hollowed-out region is used to provide a deformation space during stretching, the hollowed-out region only includes the flexible base substrate, and a film layer on the flexible base substrate of the hollowed-out region is removed. The bridge region is used for wiring, and the bridge region includes a lead line, which connects adjacent island regions.

FIG. 2 is a schematic diagram of a planar structure of a display substrate according to an embodiment of the present disclosure. In an exemplary implementation, as shown in FIG. 2, the display substrate may include a first stretch region 400 and a second stretch region 500 located on a side of the first stretch region 400 in a second direction D2. A stretchability of the first stretch region 400 is greater than a stretchability of the second stretch region 500.

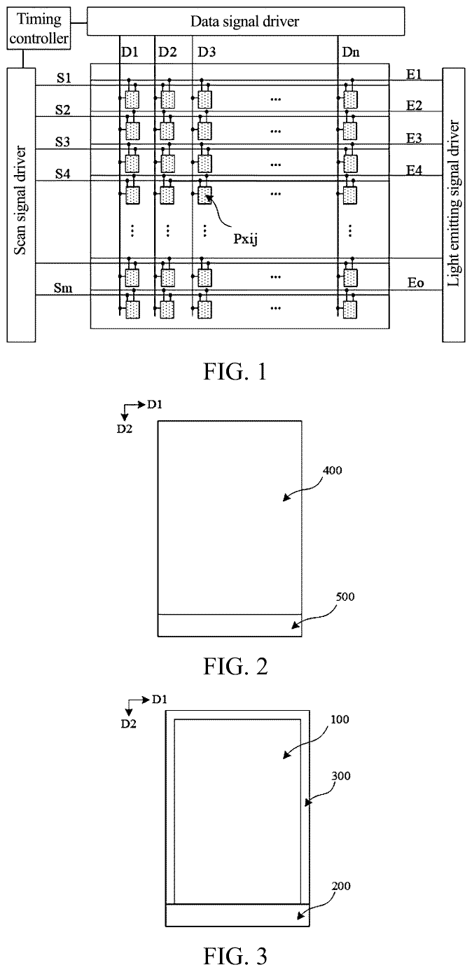

FIG. 3 is a schematic diagram of a planar structure of a display substrate according to an embodiment of the present disclosure. In an exemplary implementation, as shown in FIG. 3, the display substrate may include a display region 100 and a non-display region located around the display region. The non-display region of the display substrate may include an electrical signal input region 200 located on a side of the display region 100 in the second direction D2 and a bezel region 300 located on other sides of the display region 100. The first stretch region of the display substrate includes a display region 100 and a bezel region 300, and the second stretch region of the display substrate includes an electrical signal input region 200. A stretchability of the display region 100 and a stretchability of the bezel region 300 are greater than a stretchability of the electrical signal input region 200.

In an exemplary implementation, a stretchability of the hollowed-out region of the first stretch region 400 is greater than a stretchability of the hollowed-out region of the second stretch region 500, so that the stretchability of the first stretch region 400 is greater than the stretchability of the second stretch region 500. The display substrate according to the embodiment of the present disclosure is provided with hollowed-out regions with different stretchability in the first stretch region 400 and the second stretch region 500, so that the stretchability of the first stretch region 400 is greater than the stretchability of the second stretch region 500. In this way, when the display substrate is stretched, the main stretch deformation occurs in the first stretch region 400, the stretch deformation of the second stretch region 500 is reduced, the risk of breaking of the wiring located in the second stretch region 500 can be reduced, and the life of the display substrate can be prolonged.

In an exemplary implementation, an area of an orthographic projection of the hollowed-out region of the first stretch region 400 on a plane of the display substrate is greater than an area of an orthographic projection of the hollowed-out region of the second stretch region 500 on the plane of the display substrate, so that the stretchability of the hollowed-out region of the first stretch region 400 is greater than the stretchability of the hollowed-out region of the second stretch region 500, and the stretchability of the first stretch region 400 is greater than the stretchability of the second stretch region 500.

In an exemplary implementation, the shape of the hollowed-out region of the first stretch region 400 and the shape of the hollowed-out region of the second stretch region 500 may be the same or different, for example, both may be strip of the same shape.

In an exemplary implementation, the display substrate includes a display region 100 with a rectangular shape. In some embodiments, the display region 100 may also have a circular shape, an elliptical shape, or a polygonal shape such as a triangle and a pentagon.

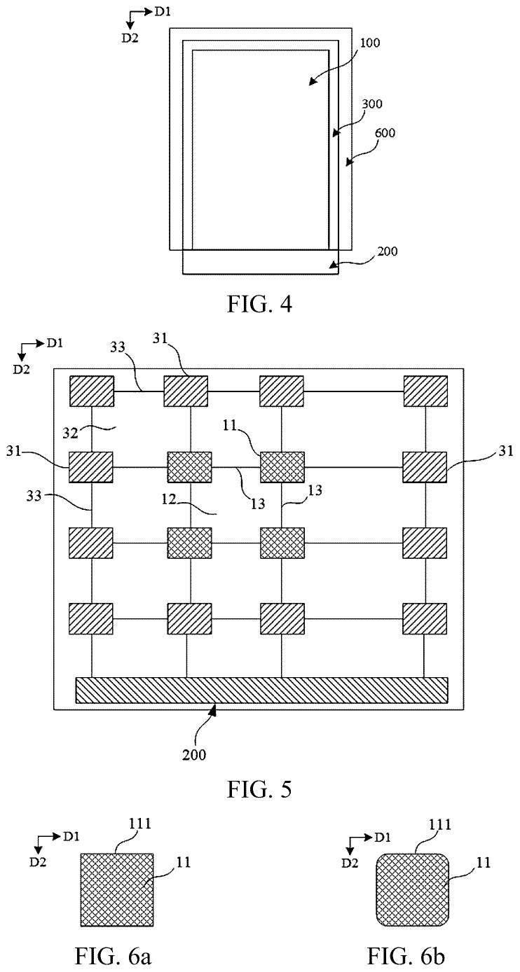

FIG. 4 is a schematic diagram of a planar structure of a display substrate according to an embodiment of the present disclosure. In an exemplary implementation, as shown in FIG. 4, the first stretch region may also include a buffer region 600. The buffer region 600 is a non-display region, and is located on a side of the bezel region 300 away from the display region 100. The buffer region 600 is configured to withstand a tensile force when the display substrate is stretched, to reduce the stretch deformation of the bezel region 300, to reduce the risk of breaking the wiring located in the bezel region 300, and to prolong the life of the display substrate.

FIG. 5 is a schematic diagram of a planar structure of a display substrate according to an embodiment of the present disclosure. In an exemplary implementation, as shown in FIG. 5, the display region of the display substrate may include a plurality of first island regions 11 arranged at intervals from each other, a first hollowed-out region 12 located between adjacent first island regions 11, and a first bridge region 13 connecting the adjacent first island regions 11 to each other. The plurality of first island regions 11 are arranged in a rectangular array in which the plurality of first island regions 11 may be arranged at intervals along a first direction D1 to form a first island region row, and the adjacent first island regions 11 in the first island region row are connected by the first bridge region 13. A plurality of second island regions 31 may be arranged at intervals along a second direction D2 to form a first island region column, and the adjacent first island regions 11 in the first island region column are connected by the first bridge region 13. The first direction D1 and the second direction D2 are both parallel to the plane of the display substrate, and the first direction D1 intersects with the second direction D2, for example, the first direction D1 is perpendicular to the second direction D2.

In an exemplary implementation, a first island region 11 includes at least one pixel unit, the at least one pixel unit may include a first sub-pixel emitting a first color light, a second sub-pixel emitting a second color light, and a third sub-pixel emitting a third color light. Each sub-pixel may include a circuit unit and a light emitting unit. The circuit unit may at least include a pixel drive circuit, and the pixel drive circuit is connected with a scan signal line, a data signal line, and a light emitting signal line, respectively, and is configured to receive a data voltage transmitted by the data signal line and output a corresponding current to the light emitting device under control of the scan signal line and the light emitting signal line. The light emitting unit may at least include a light emitting device. The light emitting device is connected with a pixel drive circuit of a sub-pixel where the light emitting device is located. The light emitting device is configured to emit light with a corresponding brightness in response to a current output by the pixel drive circuit of the sub-pixel where the light emitting device is located. The first hollowed-out region 12 may include a flexible base substrate, and the film layers of the sub-pixels in the first hollowed-out region 12 are removed. The first bridge region 13 connects the pixel units of the adjacent first island regions 11.

In an exemplary implementation, a sub-pixel may be in a shape of a rectangle, a rhombus, a pentagon, or a hexagon. Three sub-pixels may be arranged in a manner to stand side by side horizontally, in a manner to stand side by side vertically, or in a Chinese word “ [symbol] ”, etc., which is not limited here in the present disclosure.

In some exemplary implementations, a pixel unit may include four sub-pixels, and the four sub-pixels may be arranged in a manner to stand side by side horizontally, in a manner to stand side by side vertically, or in a manner of a square, which is not limited here in the present disclosure.

In an exemplary implementation, the light emitting device may include one of an organic light emitting diode (OLED), a light emitting diode (LED), a quantum dot light emitting diode (QLED). The sub-pixel may emit light, such as red light, green light, blue light or white light, by the light emitting device.

In an exemplary implementation, the light emitting device in the display substrate of the present embodiment may be a micro light emitting diode (LED), but the display substrate of the present embodiment is not limited thereto. In another embodiment, the light emitting device in the display substrate may be an organic light emitting diode (OLED) or a quantum dot light emitting diode (QLED). For example, a light emitting layer of the light emitting device in the display substrate may include an organic material, an inorganic material, quantum dots, an organic material and quantum dots, an inorganic material and quantum dots, or an organic material, an inorganic material and quantum dots.

In an exemplary implementation, the bezel region of the display substrate may include a plurality of second island regions 31 arranged at intervals from each other, a second hollowed-out region 32 located between adjacent second island regions 31, and a second bridge region 33 connecting the adjacent second island regions 31 to each other. A plurality of second island regions 31 may be arranged at intervals along the first direction D1 to form a second island region row, the adjacent second island regions 31 in the second island region row are connected by the second bridge region 33, two second island region rows are respectively disposed on opposite sides of the first island region array in the second direction D2, and the second island regions 31 in the second island region row are correspondingly connected with the first island region column. The plurality of second island regions 31 may be arranged at intervals along the second direction D2 to form a second island region column, and the adjacent second island regions 31 in the second island region column are connected by the second bridge region 33. Two second island region columns are respectively disposed on opposite sides of the first island region array in the first direction D1, and the second island regions 31 in the second island region column are correspondingly connected with the first island region row. The second island region 31 includes at least two drive units, and the at least two drive units may include a Gate driver on Array (GOA) and an Emitter driver on Array (EOA). The second hollowed-out region 32 may include a flexible base substrate, and the film layers in the drive unit of the second hollowed-out region 32 are removed.

In an exemplary implementation, at least one second island region row is located between the display region and the electrical signal input region 200, and the second island regions 31 in the second island region row are connected with the electrical signal input region 200 by the second bridge regions 33 extending in the second direction D2.

In an exemplary implementation, the second bridge region 33 connects the drive units of the adjacent second island regions 31, connects the drive units of the second island regions 31 to the pixel units of the first island regions 11, and connects the drive units of the second island regions 31 to the electrical signal input region 200.

Hereinafter, the island bridge structure in the display substrate of the present embodiment will be explained by taking the structure of the display region in the display substrate of the present embodiment as an example.

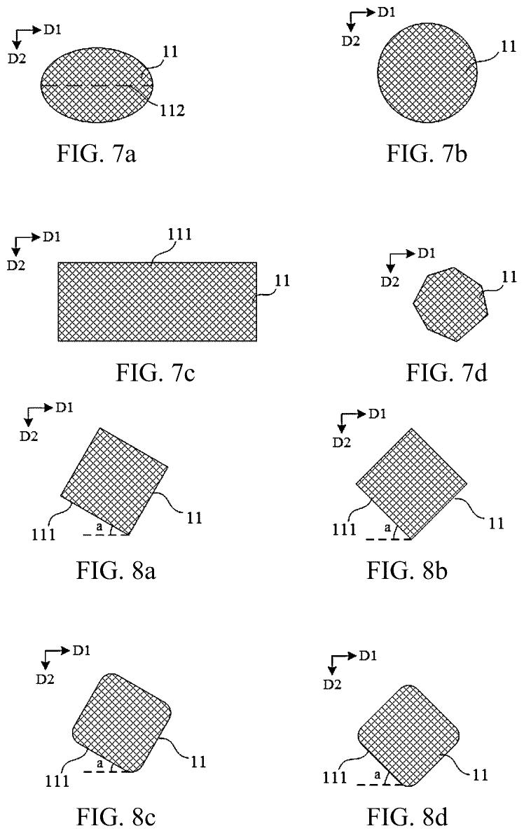

FIG. 6a is a schematic diagram of a planar structure of a first island region in a display substrate according to an embodiment of the present disclosure. FIG. 6b is a schematic diagram of a planar structure of a first island region in another display substrate according to an embodiment of the present disclosure. FIG. 7a is a schematic diagram of a planar structure of a first island region in another display substrate according to an embodiment of the present disclosure. FIG. 7b is a schematic diagram of a planar structure of a first island region in another display substrate according to an embodiment of the present disclosure. FIG. 7c is a schematic diagram of a planar structure of a first island region in another display substrate according to an embodiment of the present disclosure. FIG. 7d is a schematic diagram of a planar structure of a first island region in another display substrate according to an embodiment of the present disclosure. In an exemplary implementation, in a cross section parallel to the display substrate, the shape of the first island region 11 in the display substrate according to the embodiment of the present disclosure may include a square, and the first island region 11 includes a first edge portion 111 extending in the first direction D1, as shown in FIG. 6a. Alternatively, in a cross section parallel to the display substrate, the shape of the first island region 11 in the display substrate according to the embodiment of the present disclosure may include a rounded square, and the first island region 11 has a first edge portion 111 parallel to the first direction D1, as shown in FIG. 6b. Alternatively, in a cross section parallel to the display substrate, the shape of the first island region 11 in the display substrate according to the embodiment of the present disclosure may include an oval shape, and the first island region 11 has a long axis 112 extending along the first direction D1, as shown in FIG. 7a. Alternatively, in a cross section parallel to the display substrate, the shape of the first island region 11 in the display substrate according to the embodiment of the present disclosure may include a circle, as shown in FIG. 7b. Alternatively, in a cross section parallel to the display substrate, the shape of the first island region 11 in the display substrate according to the embodiment of the present disclosure may include a rectangle or a rounded rectangle, and the first island region 11 has a first edge portion 111 parallel to the first direction D1, as shown in FIG. 7c. Alternatively, in a cross section parallel to the display substrate, the shape of the first island region 11 in the display substrate according to the embodiment of the present disclosure may include a heptagon, as shown in FIG. 7d.

In some embodiments, in a plane parallel to the display substrate, the shape of the first island region in the display substrate according to the embodiment of the present disclosure may include a rhombus, a triangle, or other polygons such as a pentagon, a hexagon, an octagon, and a enneagon. Embodiments of the present disclosure will not be repeated here.

FIG. 8a is a schematic diagram of a planar structure of a first island region in another display substrate according to an embodiment of the present disclosure; and FIG. 8b is a schematic diagram of a planar structure of a first island region in another display substrate according to an embodiment of the present disclosure. In an exemplary implementation, in a cross section parallel to the display substrate, the shape of the first island region 11 in the display substrate according to the embodiment of the present disclosure may include a square, the first island region 11 includes a first edge portion 111, and an included angle a between the first edge portion 111 and the first direction D1 may be greater than 0 degree and less than 90 degrees. For example, the included angle a between the first edge portion 111 of the first island region 11 and the first direction D1 may be greater than or equal to 30 degrees and less than or equal to 45 degrees, as shown in FIG. 8 a. Alternatively, the included angle a between the first edge portion 111 of the first island region 11 and the first direction D1 may be greater than or equal to 60 degrees and less than 90 degrees, as shown in FIG. 8b.

FIG. 8c is a schematic diagram of a planar structure of a first island region in another display substrate according to an embodiment of the present disclosure; and FIG. 8d is a schematic diagram of a planar structure of a first island region in another display substrate according to an embodiment of the present disclosure. In an exemplary implementation, in a cross section parallel to the display substrate, the shape of the first island region 11 in the display substrate according to the embodiment of the present disclosure may include a rounded square, the first island region 11 includes a first edge portion 111, and an included angle a between the first edge portion 111 and the first direction D1 may be greater than 0 degree and less than 90 degrees. For example, the included angle a between the first edge portion 111 of the first island region 11 and the first direction D1 may be greater than or equal to 30 degrees and less than or equal to 45 degrees, as shown in FIG. 8 c. Alternatively, the included angle a between the first edge portion 111 of the first island region 11 and the first direction D1 may be greater than or equal to 60 degrees and less than 90 degrees, as shown in FIG. 8d.

In some embodiments, in a plane parallel to the display substrate, the shape of the first island region in the display substrate of the embodiment of the present disclosure may include an oval shape, and an included angle between the long axis of the first island region and the first direction D1 may be greater than 0 degree and less than 90 degrees. For example, the included angle between the long axis of the first island region and the first direction D1 may be greater than or equal to 30 degrees and less than or equal to 45 degrees, or the included angle between the long axis of the first island region and the first direction D1 may be greater than or equal to 60 degrees and less than 90 degrees.

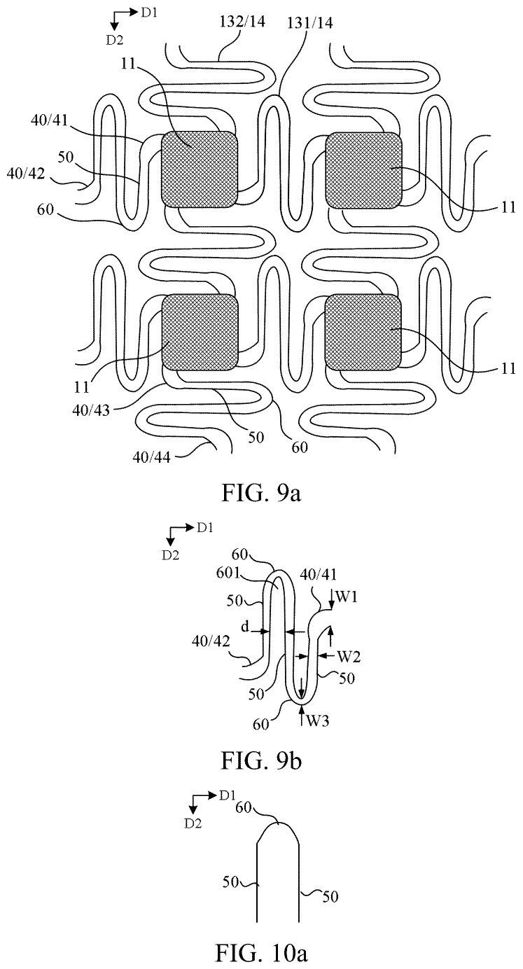

FIG. 9a is a schematic diagram of a planar structure of a first island region and a first bridge region in a display substrate according to an embodiment of the present disclosure. In an exemplary implementation, as shown in FIG. 9a, in a plane parallel to the display substrate, the display substrate of the embodiment of the present disclosure includes four first island regions 11 arranged in a rectangular array, and the shape of the four first island regions 11 each includes a rounded square which includes a first edge portion extending along the first direction D1. Two of the four first island regions 11 are arranged at intervals along the first direction D1 to form a first island region row, and two of the four first island regions 11 are arranged at intervals along the second direction D2 to form a first island region column.

In an exemplary implementation, the first bridge region includes lead lines 14 connecting adjacent first island regions 11 in the first island region row and adjacent first island regions 11 in the first island region column. A lead line 14 includes a connection section 40, a bending section 60, and a plurality of extension sections 50. A bending section 60 connects adjacent extension sections 50, a first end of the connection section 40 is connected with the first island region 11, and a second end of the connection section 40 is connected with a extension section 50.

FIG. 9b is a schematic diagram of a planar structure of a lead line in a display substrate according to an embodiment of the present disclosure. In an exemplary implementation, as shown in FIG. 9b, in a plane parallel to the display substrate, a maximum line width of the connection section 40 is W1, a maximum line width of the extension section 50 connected with the connection section 40 is W2, and a maximum line width of the bending section 60 connected with the connection section 40 is W3. The maximum line width W1 is greater than or equal to the maximum line width W2, and the maximum line width W2 is less than or equal to the maximum line width W3, thereby improving the stretchability of the display substrate, ensuring the strength of the lead lines, and preventing the lead lines from breaking during stretching. The smaller at least one of the maximum line width W1, the maximum line width W2, and the maximum line width W3, the greater the stretchability of the display substrate.

In an exemplary implementation, a maximum spacing between edges of the adjacent extension sections 50 in the first direction D1 is d, and a ratio of the maximum line width W2 of at least one of the adjacent extension sections 50 to the maximum spacing d is greater than or equal to 1/20 and less than or equal to 20, thereby improving the stretchability of the display substrate, ensuring the strength of the lead lines, and preventing the lead lines from breaking during stretching. For example, a ratio of the maximum line width W2 of at least one of the adjacent extension sections 50 to the maximum spacing d between the edges of the adjacent extension sections 50 is greater than or equal to ¼, and less than or equal to 4.

In an exemplary implementation, in a plane parallel to the display substrate, a first end of the lead line 14 is connected with a first end of an edge portion of one of the adjacent first island regions 11, and a second end of the lead line 14 is connected with a second end of an edge portion of the other of the adjacent first island regions 11. The first end and the second end are opposite ends of the edge portions of the first island regions 11, respectively, so that the stretchability of the display substrate can be increased.

In an exemplary implementation, the lead line 14 may include at least two extension sections 50, for example, a number of extension sections of 3, 4, 5, 6, or the like. The greater the number of extension sections 50, the greater the stretchability of the display substrate.

In an exemplary implementation, the shape of the bending section 60 in the lead line is arc-shaped, and, for example, the shape of the bending section 60 is U-shaped. The bending section 60 has an opening 601, one lead line includes at least two bending sections 60, and the openings 601 of the adjacent bending sections 60 are oriented oppositely, thereby increasing the length of the lead line and increasing the stretchability of the display substrate. By way of example, one opening 601 in the adjacent bending sections 60 is oriented in the second direction D2, and the other opening 601 in the adjacent bending sections 60 is oriented in the opposite direction of the second direction D2, as shown in FIG. 9b.

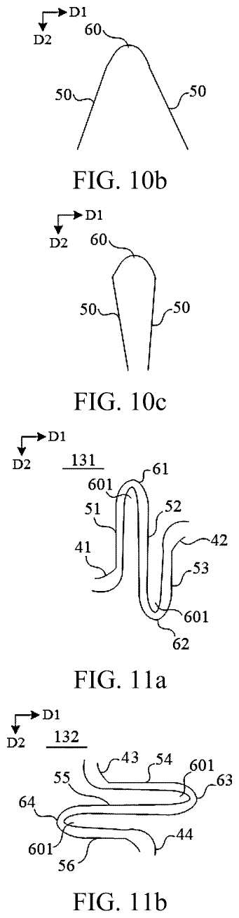

FIG. 10a is a schematic diagram of a planar structure of an extension section of a lead line in a display substrate according to an embodiment of the present disclosure; FIG. 10b is a schematic diagram of a planar structure of an extension section of a lead line in another display substrate according to an embodiment of the present disclosure; and FIG. 10c is a schematic diagram of a planar structure of an extension section of a lead line in another display substrate according to an embodiment of the present disclosure. In an exemplary implementation, central axes of the adjacent extension sections 50 in the lead line are substantially parallel, and central axes of the adjacent extension sections 50 are both parallel to the second direction D2, as shown in FIG. 10a. Alternatively, the central axes of the adjacent extension sections 50 intersect with each other, the edges of the adjacent extension sections 50 are away from each other, and the central axes of the adjacent extension sections 50 form an inner angle greater than 90 degrees, as shown in FIG. 10b. Alternatively, the central axes of the adjacent extension sections 50 intersect each other, the edges of the adjacent extension sections 50 are close to each other, and an inner angle formed by the central axes of the adjacent extension sections 50 is less than 90 degrees, as shown in FIG. 10c. The stretchability of the lead line shown in FIG. 10c is greater than or equal to the stretchability of the lead line shown in FIG. 10a, and the stretchability of the lead line shown in FIG. 10a is greater than or equal to the stretchability of the lead line shown in FIG. 10b.

FIG. 11a is a schematic diagram of a planar structure of a first lead line in a display substrate according to an embodiment of the present disclosure. In an exemplary implementation, as shown in FIG. 9a and FIG. 11a, in a plane parallel to the display substrate, the first bridge region includes a first lead line 131, the first lead line 131 is in a serpentine shape, and the first lead line 131 connects the adjacent first island regions 11 in the first island region row. The first lead line 131 includes a first connection section 41, a first extension section 51, a first bending section 61, a second extension section 52, a second bending section 62, a third extension section 53, and a second connection section 42 connected in sequence.

In an exemplary implementation, the shape of the first connection section 41 is arc-shaped, a first end of the first connection section 41 is connected with one of the adjacent first island regions 11 in the first island region row, and a second end of the first connection section 41 is connected with a first end of the first extension section 51. The first extension section 51 has a linear shape extending along the direction of the second direction D2, a first end of the first extension section 51 is connected with the second end of the first connection section 41, and a second end of the first extension section 51 extends along the opposite direction of the second direction D2 and is connected with a first end of the first bending section 61. The shape of the first bending section 61 is arc-shaped, the opening 601 of the first bending section 61 is oriented in the second direction D2, a first end of the first bending section 61 is connected with the second end of the first extension section 51, and a second end of the first bending section 61 is connected with a first end of the second extension section 52. The second extension section 52 has a linear shape extending along the direction of the second direction D2, the first end of the second extension section 52 is connected with the second end of the first bending section 61, and a second end of the second extension section 52 extends along the second direction D2 and is connected with a first end of the second bending section 62. The shape of the second bending section 62 is arc-shaped, the opening 601 of the second bending section 62 is oriented in the opposite direction of the second direction D2, the first end of the second bending section 62 is connected with the second end of the second extension section 52, and the second end of the second bending section 62 is connected with a first end of the third extension section 53. The third extension section 53 has a linear shape extending along the direction of the second direction D2, the first end of the third extension section 53 is connected with the second end of the second bending section 62, and a second end of the third extension section 53 extends along the opposite direction of the second direction D2 and is connected with a first end of the second connection section 42. The shape of the second connection section 42 is arc-shaped, the first end of the second connection section 42 is connected with the second end of the third extension section 53, and a second end of the second connection section 42 is connected with the other of the adjacent first island regions 11 in the first island region row.

In an exemplary implementation, the first end of the first connection section 41 of the first lead line 131 is connected with an edge portion of one of the adjacent first island regions 11 in the first island region row at one end thereof in the opposite direction of the second direction D2. The second end of the second connection section 42 of the first lead line 131 is connected with the edge portion of the other of the adjacent first island regions 11 in the first island region row at one end thereof in the second direction D2, thereby increasing the stretchability of the display substrate.

FIG. 11b is a schematic diagram of a planar structure of a second lead line in a display substrate according to an embodiment of the present disclosure. In an exemplary implementation, as shown in FIG. 9a and FIG. 11b, in a plane parallel to the display substrate, the first bridge region 13 includes a second lead line 132 which is in a serpentine shape and connects adjacent first island regions 11 in the first island region column. The second lead line 132 includes a third connection section 43, a fourth extension section 54, a third bending section 63, a fifth extension section 55, a fourth bending section 64, a sixth extension section 56, and a fourth connection section 44 connected in sequence.

In an exemplary implementation, the shape of the third connection section 43 is arc-shaped, a first end of the third connection section 43 is connected with one of the adjacent first island regions 11 in the first island region column, and a second end of the third connection section 43 is connected with a first end of the fourth extension section 54. The fourth extension section 54 has a linear shape extending along a direction of the first direction D1, the first end of the fourth extension section 54 is connected with the second end of the third connection section 43, and a second end of the fourth extension section 54 extends along the first direction D1 and is connected with a first end of the third bending section 63. The shape of the third bending section 63 is arc-shaped, the opening 601 of the third bending section 63 is oriented in the opposite direction of the first direction D1, the first end of the third bending section 63 is connected with the second end of the fourth extension section 54, and a second end of the third bending section 63 is connected with a first end of the fifth extension section 55. The fifth extension section 55 has a linear shape extending along a direction of the first direction D1, the first end of the fifth extension section 55 is connected with the second end of the third bending section 63, and a second end of the fifth extension section 55 extends along the opposite direction of the first direction D1 and is connected with a first end of the fourth bending section 64. The shape of the fourth bending section 64 is arc-shaped, the opening 601 of the fourth bending section 64 is oriented in the first direction D1, the first end of the fourth bending section 64 is connected with the second end of the fifth extension section 55, and a second end of the fourth bending section 64 is connected with a first end of the sixth extension section 56. The sixth extension section 56 has a linear shape extending along a direction of the first direction D1, the first end of the sixth extension section 56 is connected with the second end of the fourth bending section 64, and a second end of the sixth extension section 56 extends along the first direction D1 and is connected with a first end of the fourth connection section 44. The shape of the fourth connection section 44 is arc-shaped, the first end of the fourth connection section 44 is connected with the second end of the sixth extension section 56, and a second end of the fourth connection section 44 is connected with the other of the adjacent first island regions 11 in the first island region column.

In an exemplary implementation, the first end of the third connection section 43 of the second lead line 132 is connected with an edge portion of one of the adjacent first island regions 11 in the first island region column at one end thereof in the opposite direction of the first direction D1. The second end of the fourth connection section 44 of the second lead line 132 is connected with the edge portion of the other of the adjacent first island regions 11 in the first island region column at one end thereof in the first direction D1, thereby improving the stretchability of the display substrate.

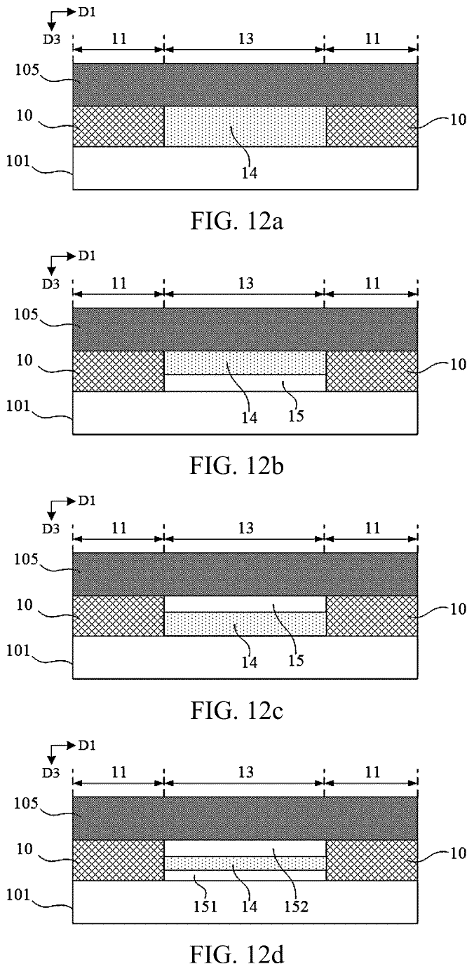

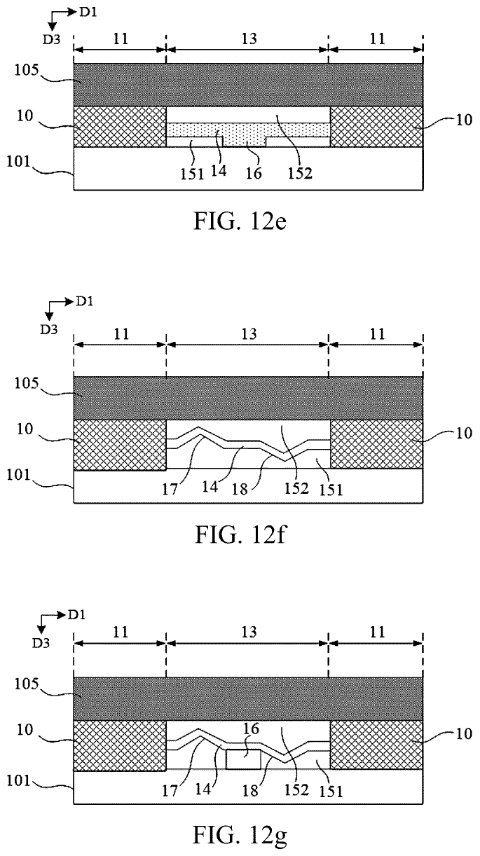

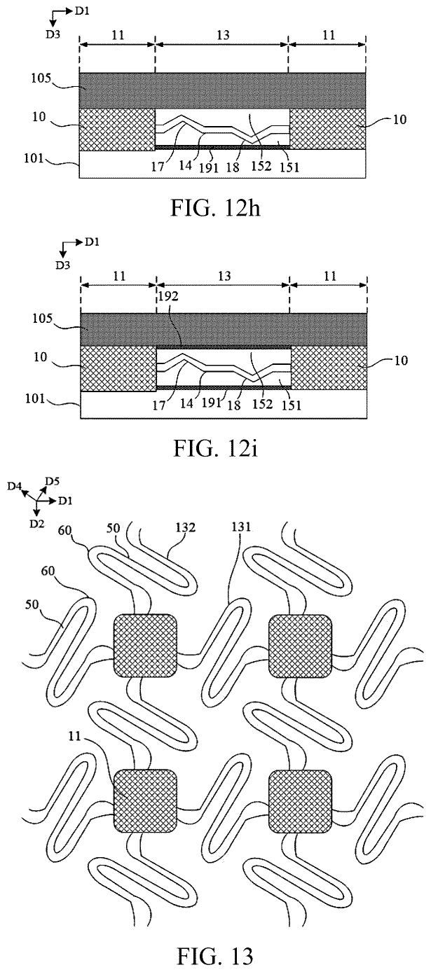

FIG. 12a is a schematic diagram of a cross sectional structure of a first island region and a first bridge region in a display substrate according to an embodiment of the present disclosure. In an exemplary implementation, as shown in FIG. 12a, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. Both ends of the lead line 14 are respectively connected with the adjacent pixel units 10, and a thickness of the lead line 14 is substantially the same as that of the pixel unit 10. A surface of the lead line 14 close to the flexible base substrate 101 is in direct contact with the flexible base substrate 101, and a surface of the lead line 14 close to the flexible film layer 105 is in direct contact with the flexible film layer 105. The flexible film layer 105 may serve as a cover plate.

FIG. 12b is a schematic diagram of a cross sectional structure of a first island region and a first bridge region in another display substrate according to an embodiment of the present disclosure. In an exemplary implementation, as shown in FIG. 12b, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. Both ends of the lead line 14 are respectively connected with the adjacent pixel units 10, a thickness of the lead line 14 is less than the thickness of the pixel unit 10, and a suspended portion 15 is provided between a surface of the lead line 14 close to the flexible base substrate 101 and the flexible base substrate 101. The surface of the lead line 14 close to the flexible base substrate 101 is not in contact with the flexible base substrate 101, and a surface of the lead line 14 close to the flexible film layer 105 is in direct contact with the flexible film layer 105. The flexible film layer 105 may serve as a cover plate.

FIG. 12c is a schematic diagram of a cross sectional structure of a first island region and a first bridge region in another display substrate according to an embodiment of the present disclosure. In an exemplary implementation, as shown in FIG. 12c, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. Both ends of the lead line 14 are respectively connected with the adjacent pixel units 10, a thickness of the lead line 14 is less than the thickness of the pixel unit 10, and a surface of the lead line 14 close to the flexible base substrate 101 is in direct contact with the flexible base substrate 101. A suspended portion 15 is provided between a surface of the lead line 14 close to the flexible film layer 105 and the flexible film layer 105, and the surface of the lead line 14 close to the flexible film layer 105 is not in contact with the flexible film layer 105. The flexible film layer 105 may serve as a cover plate.

FIG. 12d is a schematic diagram of a cross sectional structure of a first island region and a first bridge region in another display substrate according to an embodiment of the present disclosure. In an exemplary implementation, as shown in FIG. 12d, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. The lead line 14 is in a linear shape, both ends of the lead line 14 are respectively connected with the adjacent pixel units 10, and a thickness of the lead line 14 is less than that of the pixel unit 10. A first suspended portion 151 is provided between a surface of the lead line 14 close to the flexible base substrate 101 and the flexible base substrate 101, and the surface of the lead line 14 close to the flexible base substrate 101 is not in contact with the flexible base substrate 101. A second suspended portion 152 is provided between a surface of the lead line 14 close to the flexible film layer 105 and the flexible film layer 105, and the surface of the lead line 14 close to the flexible film layer 105 is not in contact with the flexible film layer 105. The flexible film layer 105 may serve as a cover plate.

FIG. 12e is a schematic diagram of a cross sectional structure of a first island region and a first bridge region in another display substrate according to an embodiment of the present disclosure. In an exemplary implementation, as shown in FIG. 12e, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. The lead line 14 is in a linear shape, and both ends of the lead line 14 are connected with the adjacent pixel units 10, respectively. A bump 16 is provided in a partial region of a surface of the lead line 14 close to the flexible base substrate 101, and the bump 16 is in direct contact with the flexible base substrate 101. A first suspended portion 151 is provided between a partial region of a surface of the lead line 14 close to the flexible base substrate 101 and the flexible base substrate 101. For example, a first suspended portion 151 is provided between a region of a surface of the lead line 14 close to the flexible base substrate 101 except the bump 16 and the flexible base substrate 101. A second suspended portion 152 is provided between a surface of the lead line 14 close to the flexible film layer 105 and the flexible film layer 105, and the surface of the lead line 14 close to the flexible film layer 105 is not in contact with the flexible film layer 105. The flexible film layer 105 may serve as a cover plate.

FIG. 12f is a schematic diagram of a cross sectional structure of a first island region and a first bridge region in another display substrate according to an embodiment of the present disclosure. In an exemplary implementation, as shown in FIG. 12f, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. Both ends of the lead line 14 are respectively connected with the adjacent pixel units 10, and a first suspended portion 151 is provided between a surface of the lead line 14 close to the flexible base substrate 101 and the flexible base substrate 101. A second suspended portion 152 is provided between a surface of the lead line 14 close to the flexible film layer 105 and the flexible film layer 105. The flexible film layer 105 may serve as a cover plate.

In an exemplary implementation, the lead line 14 is in a serpentine shape. The serpentine shape of the lead line 14 may be naturally curved (in its own state), or may be curved after an external force is applied. The lead line 14 includes at least one first bending portion 17 and at least one second bending portion 18, and the first bending portion 17 is bent in a direction opposite to the bending direction of the second bending portion 18. For example, the first bending portion 17 is bent towards an opposite direction of a third direction D3, and the second bending portion 18 is bent towards the third direction D3. The bent ends of the first bending portion 17 and the second bending portion 18 may be arc-shaped. The lead line 14 increases the stretchability of the display substrate by the first bending portion 17 and the second bending portion 18. The third direction D3 is a direction perpendicular to the plane of the display substrate.

FIG. 12g is a schematic diagram of a cross sectional structure of a first island region and a first bridge region in another display substrate according to an embodiment of the present disclosure. In an exemplary implementation, as shown in FIG. 12g, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. Both ends of the lead line 14 are connected with the adjacent pixel units 10, respectively, a bump 16 is provided in a partial region of a surface of the lead line 14 close to the flexible base substrate 101, and the bump 16 is in direct contact with the flexible base substrate 101. A first suspended portion 151 is provided between a partial region of a surface of the lead line 14 close to the flexible base substrate 101 and the flexible base substrate 101. A second suspended portion 152 is provided between a surface of the lead line 14 close to the flexible film layer 105 and the flexible film layer 105, and the surface of the lead line 14 close to the flexible film layer 105 is not in contact with the flexible film layer 105. The flexible film layer 105 may serve as a cover plate.

In an exemplary implementation, the lead line 14 is in a serpentine shape. The serpentine shape of the lead line 14 may be naturally curved (in its own state), or may be curved after an external force is applied. The lead line 14 includes at least one first bending portion 17 and at least one second bending portion 18, and the first bending portion 17 is bent in a direction opposite to the bending direction of the second bending portion 18. For example, the first bending portion 17 is bent towards the opposite direction of the third direction D3, and the second bending portion 18 is bent towards the third direction D3. The bent ends of the first bending portion 17 and the second bending portion 18 may be arc-shaped. The lead line 14 increases the stretchability of the display substrate by the first bending portion 17 and the second bending portion 18. The third direction D3 is a direction perpendicular to the plane of the display substrate.

FIG. 12h is a schematic diagram of a cross sectional structure of a first island region and a first bridge region in another display substrate according to an embodiment of the present disclosure. In an exemplary implementation, as shown in FIG. 12h, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. Both ends of the lead line 14 are respectively connected with the adjacent pixel units 10, and a first suspended portion 151 is provided between a surface of the lead line 14 close to the flexible base substrate 101 and the flexible base substrate 101. A second suspended portion 152 is provided between a surface of the lead line 14 close to the flexible film layer 105 and the flexible film layer 105. The flexible film layer 105 may serve as a cover plate.

In an exemplary implementation, the lead line 14 is in a serpentine shape. The serpentine shape of the lead line 14 may be naturally curved (in its own state), or may be curved after an external force is applied. The lead line 14 includes at least one first bending portion 17 and at least one second bending portion 18, and the first bending portion 17 is bent in a direction opposite to the bending direction of the second bending portion 18. For example, the first bending portion 17 is bent towards the opposite direction of the third direction D3, and the second bending portion 18 is bent towards the third direction D3. The bent ends of the first bending portion 17 and the second bending portion 18 may be arc-shaped. The lead line 14 increases the stretchability of the display substrate by the first bending portion 17 and the second bending portion 18. The third direction D3 is a direction perpendicular to the plane of the display substrate.

In an exemplary implementation, the first bridge region 13 of the display substrate also includes a first anti-adhesion layer 191. The first anti-adhesion layer 191 is disposed on a side of the flexible base substrate 101 close to the lead line 14, and is located between the lead line 14 and the flexible base substrate 101, and an orthographic projection of the first anti-adhesion layer 191 on the flexible base substrate 101 overlaps with an orthographic projection of the lead line 14 on the flexible base substrate 101. The first anti-adhesion layer 191 can prevent the lead line 14 from being bonded together with the flexible base substrate 101.

In some embodiments, the first bridge region of the display substrate further includes a second anti-adhesion layer. The second anti-adhesion layer is disposed on a side of the flexible film layer close to the lead line, and an orthographic projection of the second anti-adhesion layer on the flexible base substrate overlaps with the orthographic projection of the lead line on the flexible base substrate. The second anti-adhesion layer can prevent the lead line from being bonded together with the flexible film layer.

FIG. 12i is a schematic diagram of a cross sectional structure of a first island region and a first bridge region in another display substrate according to an embodiment of the present disclosure. In an exemplary implementation, as shown in FIG. 12i, in a plane perpendicular to the display substrate, the display region of the display substrate includes a first island region 11 and a first bridge region 13 connecting the adjacent first island regions 11. The first island region 11 includes a flexible base substrate 101, a pixel unit 10 disposed on the flexible base substrate 101, and a flexible film layer 105 disposed on a side of the pixel unit 10 away from the flexible base substrate 101. The first bridge region 13 includes a flexible base substrate 101, a lead line 14 disposed on a side of the flexible base substrate 101, and a flexible film layer 105 disposed on a side of the lead line 14 away from the flexible base substrate 101. Both ends of the lead line 14 are respectively connected with the adjacent pixel units 10, and a first suspended portion 151 is provided between a surface of the lead line 14 close to the flexible base substrate 101 and the flexible base substrate 101. A second suspended portion 152 is provided between a surface of the lead line 14 close to the flexible film layer 105 and the flexible film layer 105. The flexible film layer 105 may serve as a cover plate.

In an exemplary implementation, the lead line 14 is in a serpentine shape. The serpentine shape of the lead line 14 may be naturally curved (in its own state), or may be curved after an external force is applied. The lead line 14 includes at least one first bending portion 17 and at least one second bending portion 18, and the first bending portion 17 is bent in a direction opposite to the bending direction of the second bending portion 18. For example, the first bending portion 17 is bent towards the opposite direction of the third direction D3, and the second bending portion 18 is bent towards the third direction D3. The bent ends of the first bending portion 17 and the second bending portion 18 may be arc-shaped. The lead line 14 increases the stretchability of the display substrate by the first bending portion 17 and the second bending portion 18. The third direction D3 is a direction perpendicular to the plane of the display substrate.

In an exemplary implementation, the first bridge region 13 of the display substrate further includes a first anti-adhesion layer 191 and a second anti-adhesion layer 192. The first anti-adhesion layer 191 is disposed on a side of the flexible base substrate 101 close to the lead line 14, an orthographic projection of the first anti-adhesion layer 191 on the flexible base substrate 101 overlaps with the orthographic projection of the lead line 14 on the flexible base substrate 101, and the first anti-adhesion layer 191 may prevent the lead line 14 from being bonded together with the flexible base substrate 101. The second anti-adhesion layer 192 is disposed on a side of the flexible film layer 105 close to the lead line 14, an orthographic projection of the second anti-adhesion layer 192 on the flexible base substrate 101 overlaps with the orthographic projection of the lead line 14 on the flexible base substrate 101, and the second anti-adhesion layer 192 can prevent the lead line 14 from being bonded together with the flexible film layer 105.

FIG. 13 is a schematic diagram of a planar structure of a first island region and a first bridge region in another display substrate according to an embodiment of the present disclosure. As shown in FIG. 13, the structure of the first island region and the first bridge region in the display substrate of the present exemplary embodiment is substantially the same as that of the display substrate of the embodiment shown in FIG. 9a, except that the extension sections 50 of the first lead line 131 are in a linear shape extending along a direction of a fifth direction D5, and the central axes of the adjacent extension sections 50 of the first lead line 131 are substantially parallel. The fifth direction D5 is parallel to the plane of the display substrate, and the fifth direction D5 intersects with both the first direction D1 and the second direction D2.

In an exemplary implementation, the extension sections 50 of the second lead line 132 are in a linear shape extending along a direction of a fourth direction D4, and the central axes of the adjacent extension sections 50 of the second lead line 132 are substantially parallel. The fourth direction D4 is parallel to the plane of the display substrate, and the fourth direction D4 intersects with each of the fifth direction D5, the first direction D1, and the second direction D2.

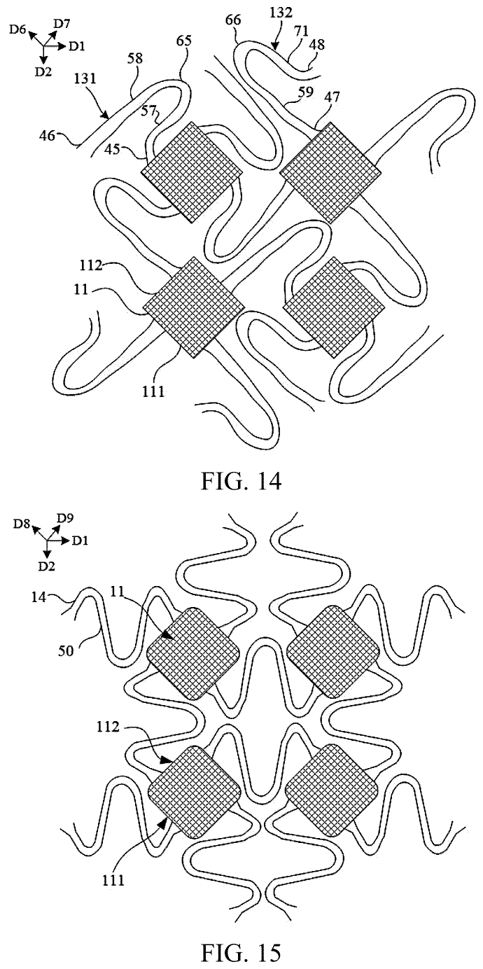

FIG. 14 is a schematic diagram of a planar structure of a first island region and a first bridge region in another display substrate according to an embodiment of the present disclosure. As shown in FIG. 14, the structure of the first island region and the first bridge region in the display substrate of the present exemplary embodiment is substantially the same as that of the display substrate of the embodiment shown in FIG. 9a, except that the shape of the first island region 11 includes square, and the first island region 11 includes two first edge portions 111 disposed oppositely and two second edge portions 112 disposed oppositely. The first edge portions 111 extend along a sixth direction D6, the second edge portions 112 extend along a seventh direction D7, the sixth direction D6 and the seventh direction D7 are parallel to the plane of the display substrate, and the sixth direction D6 and the seventh direction D7 are perpendicular to each other. The sixth direction D6 intersects with the first direction D1 and the second direction D2, and the seventh direction D7 intersects with the first direction D1 and the second direction D2.

In an exemplary implementation, the first lead line 131 connects adjacent first island regions 11 in the first island region row. The first end of the first lead line 131 is connected with the first edge portion 111 of one of the adjacent first island regions 11, and the second end of the first lead line 131 is connected with the second edge portion 112 of the other of the adjacent first island regions 11. The first lead line 131 includes a fifth connection section 45, a seventh extension section 57, a fifth bending section 65, an eighth extension section 58, and a sixth connection section 46 connected in sequence. A first end of the fifth connection section 45 is connected with the second edge portion 112 of one of the adjacent first island regions 11, a second end of the fifth connection section 45 is connected with a first end of the seventh extension section 57, and a second end of the seventh extension section 57 is connected with a first end of the fifth bending section 65. A second end of the fifth bending section 65 is connected with a first end of the eighth extension section 58, a second end of the eighth extension section 58 is connected with a first end of the sixth connection section 46, and a second end of the sixth connection section 46 is connected with the first edge portion 111 of the other of the adjacent first island regions 11.

In an exemplary implementation, the central axes of both the seventh extension section 57 and the eighth extension section 58 are substantially parallel to the second edge portion 112.

In an exemplary implementation, at least part of the first lead lines 131 are adjacent to each other, and the openings of the fifth bending sections 65 of the adjacent first lead lines 131 are oriented oppositely. By way of example, the opening of the fifth bending section 65 of one of the adjacent first lead lines 131 is oriented in the seventh direction D7, and the opening of the fifth bending section 65 of the other of the adjacent first lead lines 131 is oriented in the opposite direction of the seventh direction D7.

In an exemplary implementation, the oppositely disposed edge portions of one first island region 11 are each connected with one first lead line 131, and the openings of the fifth bending sections 65 of the first lead lines 131 connected with the opposite edge portions of one first island region 11 are oriented oppositely. For example, the two oppositely disposed second edge portions 112 of the first island region 11 are each connected with one first lead line 131, and the openings of the fifth bending sections 65 of the first lead lines 131 connected with the two second edge portions 112 of one first island region 11 are oriented oppositely. Alternatively, the two oppositely disposed first edge portions 111 of the first island region 11 are each connected with one first lead line 131, and the openings of the fifth bending sections 65 of the first lead lines 131 connected with the two first edge portions 111 of one first island region 11 are oriented oppositely.

In an exemplary implementation, the second lead line 132 connects adjacent first island regions 11 in the first island region column. The first end of the second lead line 132 is connected with the first edge portion 111 of one of the adjacent first island regions 11, and the second end of the first lead line 131 is connected with the second edge portion 112 of the other of the adjacent first island regions 11. The second lead line 132 includes a seventh connection section 47, a ninth extension section 59, a sixth bending section 66, a tenth extension section 71, and an eighth connection section 48 connected in sequence. A first end of the seventh connection section 47 is connected with one of the adjacent first island regions 11, a second end of the seventh connection section 47 is connected with a first end of the ninth extension section 59, and a second end of the ninth extension section 59 is connected with a first end of the sixth bending section 66. A second end of the sixth bending section 66 is connected with a first end of the tenth extension section 71, a second end of the tenth extension section 71 is connected with a first end of the eighth connection section 48, and a second end of the eighth connection section 48 is connected with the other of the adjacent first island regions 11.

In an exemplary implementation, the central centerlines of both the ninth extension section 59 and the tenth extension section 71 are substantially parallel to the first edge portion 111.

In an exemplary implementation, at least part of the second lead lines 132 are adjacent to each other, and the openings of the sixth bending sections 66 of the adjacent second lead lines 132 are oriented oppositely. By way of example, one of the sixth bending sections 66 of the adjacent second lead lines 132 is oriented in the sixth direction D6, and the other of the sixth bending sections 66 of the adjacent second lead lines 132 is oriented in the opposite direction of the sixth direction D6.

In an exemplary implementation, the second lead lines 132 are respectively connected with the oppositely disposed edge portions of the first island region 11, and the openings of the sixth bending sections 66 of the second lead lines 132 connected with the oppositely disposed edge portions are oriented oppositely. For example, the second lead lines 132 are respectively connected with the two oppositely disposed first edge portions 111 of the first island region 11, and the openings of the sixth bending sections 66 of the second lead lines 132 connected with the two oppositely disposed first edge portions 111 are oriented oppositely. Alternatively, the second lead lines 132 are respectively connected with the two oppositely disposed second edge portions 112 of the first island region 11, and the openings of the sixth bending sections 66 of the second lead lines 132 connected with the two oppositely disposed second edge portions 112 are oriented oppositely.

FIG. 15 is a schematic diagram of a planar structure of a first island region and a first bridge region in another display substrate according to an embodiment of the present disclosure. As shown in FIG. 15, the structure of the first island region and the first bridge region in the display substrate of the present exemplary embodiment is substantially the same as that of the display substrate of the embodiment shown in FIG. 9a, except that the shape of the first island region 11 includes a rounded square, and the first island region 11 includes a first edge portion 111 extending along an eighth direction D8 and a second edge portion 112 extending along a ninth direction D9. The eighth direction D8 and the ninth direction D9 are both parallel to the plane of the display substrate, the eighth direction D8 and the ninth direction D9 are perpendicular to each other, the eighth direction D8 intersects with both the first direction D1 and the second direction D2, and the ninth direction D9 intersects with both the first direction D1 and the second direction D2.

In an exemplary implementation, the first bridge region includes a lead line 14 connecting adjacent first island regions 11. The central axes of the adjacent extension sections 50 of one lead line 14 intersect with each other, and the edges of the adjacent extension sections 50 of the lead line 14 are away from each other.

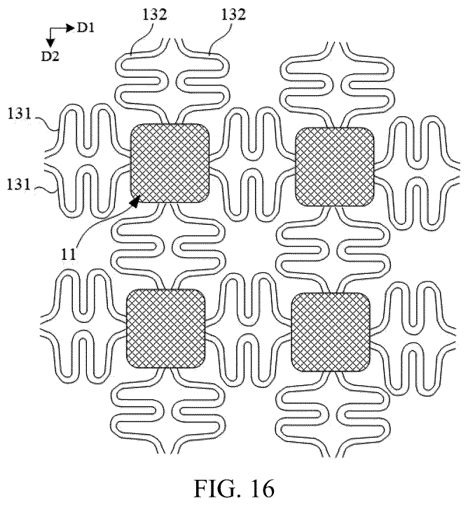

FIG. 16 is a schematic diagram of a planar structure of a first island region and a first bridge region in another display substrate according to an embodiment of the present disclosure. As shown in FIG. 16, the structure of the first island region and the first bridge region of display substrate of the present exemplary embodiment is substantially the same as that of the display substrate of the embodiment shown in FIG. 9a, except that two adjacent first lead lines 131 are provided between the adjacent first island regions 11 in the first island region row, and the two adjacent first lead lines 131 are mirrored. For example, the two first lead lines 131 are mirrored with the center line of the first island region 11 in the first direction D1 as an axis. The bending sections of the two adjacent first lead lines 131 are oppositely disposed, and the openings of the oppositely disposed bending sections are oriented oppositely. Two adjacent second lead lines 132 are provided between the adjacent first island regions 11 in the first island region column, and the two adjacent second lead lines 132 are mirrored. For example, the two adjacent second lead lines 132 are mirrored with the center line of the first island region 11 in the second direction D2 as an axis. The bending sections of the two adjacent second lead lines 132 are oppositely disposed, and the openings of the oppositely disposed bending sections are oriented oppositely.

The display substrate of the present exemplary embodiment increases the stretchability of the display substrate by providing a plurality of lead lines between adjacent island regions.

The present disclosure also provides a display apparatus which includes the aforementioned display substrate. The display apparatus may be any product or component with a display function, such as a mobile phone, a tablet computer, a television, a display, a laptop computer, a digital photo frame, or a navigator, which is not limited in the embodiments of the present invention.

Although implementations disclosed in the present disclosure are described as above, the described contents are only implementations which are used for facilitating understanding of the present disclosure, but are not intended to limit the present invention. Any skilled person in the art to which the present disclosure pertains may make any modification and variation in a form and details of implementation without departing from the spirit and scope of the present disclosure. However, the patent protection scope of the present invention should be subject to the scope defined in the appended claims.

1. A display substrate, comprising a plurality of island regions arranged at intervals, a hollowed-out region located between adjacent island regions, and a bridge region connecting the adjacent island regions to each other, wherein the bridge region comprises a lead line, the lead line comprises a connection section, a bending section, and a plurality of extension sections, the bending section connects adjacent extension sections, a first end of the connection section is connected with an island region, a second end of the connection section is connected with an extension section, a maximum line width of the connection section is greater than or equal to a maximum line width of the extension section connected therewith, and a maximum line width of the extension section is less than or equal to a maximum line width of the bending section connected therewith.

2. The display substrate of claim 1, wherein a ratio of a maximum line width of at least one of the adjacent extension sections to a maximum spacing between edges of the adjacent extension sections is greater than or equal to 1/20 and less than or equal to 20.

3. The display substrate of claim 2, wherein a ratio of a maximum line width of at least one of the adjacent extension sections to a maximum spacing between the edges of the adjacent extension sections is greater than or equal to ¼ and less than or equal to 4.

4. The display substrate of claim 1, wherein the lead line is in a serpentine shape in a plane parallel to the display substrate.

5. The display substrate of claim 1, wherein in a plane parallel to the display substrate, a first end of the lead line is connected with a first end of an edge portion of one of the adjacent island regions, a second end of the lead line is connected with a second end of an edge portion of the other of the adjacent island regions, and the first end and the second end are opposite ends of edge portions of the island regions.

6. The display substrate of claim 1, wherein central axes of the adjacent extension sections are substantially parallel; and/or, central axes of the adjacent extension sections intersect with each other, and edges of the adjacent extension sections are away from each other; and/or, central axes of the adjacent extension sections intersect with each other, and edges of the adjacent extension sections are close to each other.

7. The display substrate of claim 1, wherein a shape of the bending section is arc-shaped; or
wherein the bending section has an opening, the lead line comprises a plurality of bending sections, and openings of adjacent bending sections are oriented oppositely; and/or, the bending section has an opening, the lead line comprises one bending section, at least part of lead lines are adjacent to each other, and the openings of the bending sections of adjacent lead lines are oriented oppositely.

8. (canceled)

9. The display substrate of claim 1, wherein at least two lead lines are connected between the adjacent island regions, the at least two lead lines are adjacent to each other, and adjacent lead lines are mirrored.

10. The display substrate of claim 1, wherein the plurality of island regions are arranged at intervals to form an island region row, the bridge region comprises a first lead line, the first lead line is in a serpentine shape, the first lead line connects adjacent island regions in the island region row; the first lead line comprises a first connection section, a first extension section, a first bending section, a second extension section, a second bending section, a third extension section and a second connection section connected in sequence; a first end of the first connection section is connected with one of the adjacent island regions in the island region row, a second end of the first connection section is connected with a first end of the first extension section, a second end of the first extension section is connected with a first end of the first bending section, a second end of the first bending section is connected with a first end of the second extension section, a second end of the second extension section is connected with a first end of the second bending section, a second end of the second bending section is connected with a first end of the third extension section, a second end of the third extension section is connected with a first end of the second connection section, and a second end of the second connection section is connected with the other of the adjacent island regions in the island region row.

11. The display substrate of claim 1, wherein the plurality of island regions are arranged at intervals to form an island region row, the bridge region comprises a first lead line, the first lead line is in a serpentine shape, the first lead line connects adjacent island regions in the island region row; the first lead line comprises a fifth connection section, a seventh extension section, a fifth bending section, an eighth extension section and a sixth connection section connected in sequence; a first end of the fifth connection section is connected with one of the adjacent island regions, a second end of the fifth extension section is connected with a first end of the seventh extension section, a second end of the seventh extension section is connected with a first end of the fifth bending section, a second end of the fifth bending section is connected with a first end of the eighth extension section, a second end of the eighth extension section is connected with a first end of the sixth connection section, and a second end of the sixth connection section is connected with the other of the adjacent island regions.

12. The display substrate of claim 1, wherein the plurality of island regions are arranged at intervals to form an island region column, the bridge region comprises a second lead line, the second lead line is in a serpentine shape, the second lead line connects adjacent island regions in the island region column; the second lead line comprises a third connection section, a fourth extension section, a third bending section, a fifth extension section, a fourth bending section, a sixth extension section and a fourth connection section connected in sequence; a first end of the third connection section is connected with one of the adjacent island regions in the island region column, a second end of the third connection section is connected with a first end of the fourth extension section, a second end of the fourth extension section is connected with a first end of the third bending section, a second end of the third bending section is connected with a first end of the fifth extension section, a second end of the fifth extension section is connected with a first end of the fourth bending section, a second end of the fourth bending section is connected with a first end of the sixth extension section, a second end of the sixth extension section is connected with a first end of the fourth connection section, and a second end of the fourth connection section is connected with the other of the adjacent island regions in the island region column.

13. The display substrate of claim 1, wherein the plurality of island regions are arranged at intervals to form an island region column, the bridge region comprises a second lead line, the second lead line is in a serpentine shape, the second lead line connects adjacent island regions in the island region column; the second lead line comprises a seventh connection section, a ninth extension section, a sixth bending section, a tenth extension section and an eighth connection section connected in sequence; a first end of the seventh connection section is connected with one of the adjacent island regions, a second end of the seventh connection section is connected with a first end of the ninth extension section, a second end of the ninth extension section is connected with a first end of the sixth bending section, a second end of the sixth bending section is connected with a first end of the tenth extension section, a second end of the tenth extension section is connected with a first end of the eighth connection section, and a second end of the eighth connection section is connected with the other of the adjacent island regions.

14. The display substrate of claim 1, wherein, in a cross section parallel to the display substrate, a shape of the island region comprises at least one of a rectangle, a rounded rectangle, an oblong, an oval, a circle, and a heptagon; or
wherein, in a cross section parallel to the display substrate, a shape of the island region comprises at least one of a rectangle and a rounded rectangle, and the island region comprises a first edge portion parallel to a first direction; or, an included angle between the first edge portion and the first direction is greater than 0 degree and less than 90 degrees.

15. (canceled)

16. The display substrate of claim 1, wherein the bridge region further comprises a flexible base substrate, a lead line disposed on a side of the flexible base substrate, and a flexible film layer disposed on a side of the lead line away from the flexible base substrate, a surface of the lead line close to the flexible base substrate is in direct contact with the flexible base substrate, and a surface of the lead line close to the flexible film layer is in direct contact with the flexible film layer.

17. The display substrate of claim 1, wherein the bridge region comprises a flexible base substrate, a lead line disposed on a side of the flexible base substrate, and a flexible film layer disposed on a side of the lead line away from the flexible base substrate, wherein a gap is provided between a surface of the lead line close to the flexible base substrate and the flexible base substrate, and a surface of the lead line close to the flexible film layer is in direct contact with the flexible film layer; or
wherein the bridge region comprises a flexible base substrate, a lead line disposed on a side of the flexible base substrate, and a flexible film layer disposed on a side of the lead line away from the flexible base substrate, wherein a surface of the lead line close to the flexible base substrate is in direct contact with the flexible base substrate, and a suspended portion is disposed between a surface of the lead line close to the flexible film layer and the flexible film layer.

18. (canceled)

19. The display substrate of claim 1, wherein the bridge region comprises a flexible base substrate, a lead line disposed on a side of the flexible base substrate, and a flexible film layer disposed on a side of the lead line away from the flexible base substrate, wherein a first suspended portion is disposed between a surface of the lead line close to the flexible base substrate and the flexible base substrate, and a second suspended portion is disposed between a surface of the lead line close to the flexible film layer and the flexible film layer.

20. The display substrate of claim 19, wherein the lead line is in a serpentine shape in a plane perpendicular to the display substrate; and
wherein a bump is disposed on a surface of the lead line close to the flexible base substrate, and the bump is in direct contact with the flexible base substrate.

21. (canceled)

22. The display substrate of claim 1, wherein the bridge region comprises a flexible base substrate, a lead line disposed on a side of the flexible base substrate, and a flexible film layer disposed on a side of the lead line away from the flexible base substrate, wherein a bump is disposed on a surface of the lead line close to the flexible base substrate, the bump is in direct contact with the flexible base substrate, a first suspended portion is disposed between at least a part of the surface of the lead line close to the flexible base substrate and the flexible base substrate, and a second suspended portion is disposed between a surface of the lead line close to the flexible film layer and the flexible film layer.

23. The display substrate of claim 1, wherein the bridge region comprises a flexible base substrate, a lead line disposed on a side of the flexible base substrate, and a flexible film layer disposed on a side of the lead line away from the flexible base substrate, and the bridge region further comprises a first anti-adhesion layer disposed on a side of the flexible base substrate close to the lead line, and an orthographic projection of the first anti-adhesion layer on the flexible base substrate overlaps with an orthographic projection of the lead line on the flexible base substrate; and/or, the bridge region further comprises a second anti-adhesion layer disposed on a side of the flexible film layer close to the lead line, and an orthographic projection of the second anti-adhesion on the flexible base substrate overlaps with an orthographic projection of the lead line on the flexible base substrate.

24. A display apparatus, comprising the display substrate of claim 1.
